(19) United States
(12) Patent Application Publication
(10) Pub. No.: US 2025/0285929 A1
(43) Pub. Date: Sep. 11, 2025

(54) SEMICONDUCTOR DEVICE AND METHOD FOR MANUFACTURING SEMICONDUCTOR DEVICE

(71) Applicant: Renesas Electronics Corporation, Tokyo (JP)

(72) Inventor: Ryota KURODA, Tokyo (JP)

(21) Appl. No.: 19/026,968

(22) Filed: Jan. 17, 2025

(30) Foreign Application Priority Data
Mar. 6, 2024 (JP) 2024-033608

(51) Int. Cl. H01L 23/31; H01L 21/56; H01L 23/29; H10D 84/00; H10D 84/01

(52) U.S. Cl. CPC H01L 23/3171; H01L 21/56; H10D 84/0109; H10D 84/161; H01L 23/291

(57) ABSTRACT

A semiconductor device is provided, which includes a boundary member between an auxiliary element and a main surface of a semiconductor substrate to reduce the step of a protective film covering the auxiliary element. A semiconductor device is provided, comprising a semiconductor substrate having a first main surface having a first region, a second region, and a third region located between the first region and the second region in plan view, a transistor formed in the first region, an auxiliary element formed in the second region, a boundary member formed in the third region, and a protective film covering the auxiliary element and the boundary member. The height from the first main surface to the upper surface of the boundary member is lower than the height from the first main surface to the upper surface of the auxiliary element.

### CROSS-REFERENCE TO RELATED APPLICATIONS

The disclosure of Japanese Patent Application No. 2024-033608 filed on Mar. 6, 2024, including the specification, drawings and abstract is incorporated herein by reference in its entirety.

### BACKGROUND

The present disclosure relates to a semiconductor device and a method for manufacturing semiconductor devices.

There are disclosed techniques listed below.
[Patent Document 1] Japanese Unexamined Patent Application Publication No. 2022-82244

Patent Document 1 discloses a semiconductor device in which an IGBT (Insulated Gate Bipolar Transistor) and an internal element are formed.

### SUMMARY

When forming a protective film made of PSG (Phosphorus Silicate Glass) on the embedded elements of Patent Document 1, the step between the auxiliary element and the main surface of the semiconductor substrate becomes large. If an electrode is formed here, a metal film remains at the edge of the step, causing a short circuit when forming the upper wiring. Therefore, it was necessary to apply SOG (Spin on Glass) to the protective film to smooth the step. Accordingly, an object of the present disclosure is to provide a semiconductor device that reduces the step of the protective film covering the auxiliary element by providing a boundary member between the auxiliary element and the main surface of the semiconductor substrate.

Other objects and novel features will become apparent from the description of this specification and the accompanying drawings.

According to an embodiment, the semiconductor device reduces the step of the protective film of the auxiliary element.

According to the embodiment, it is possible to eliminate the residue of the metal film on the protective film without applying SOG to the protective film.

### BRIEF DESCRIPTION OF THE DRAWINGS

FIG. 1 is a schematic diagram showing the layout configuration of a semiconductor chip on which related semiconductor devices are mounted.

FIG. 2 is a cross-sectional view of the related semiconductor device.

FIG. 3 A is a cross-sectional view of a related auxiliary element and the protective film covering it, and FIG. 3B is a cross-sectional view of an auxiliary element according to an embodiment and the protective film covering it.

FIGS. 4A-4J are cross-sectional views showing a method for manufacturing a related auxiliary element.

FIGS. 5A-5I are cross-sectional views showing a method for manufacturing an auxiliary element according to an embodiment.

FIG. 6A is an upper surface view of an auxiliary element and a boundary member, and FIG. 6B and FIG. 6C are cross-sectional views showing the limits of the width of the boundary member.

### DETAILED DESCRIPTION

Embodiment. Hereinafter, embodiments of the present invention will be described with reference to the drawings. However, the invention subject to the claims is not limited to the following embodiments. Furthermore, not all configurations described in the embodiments are essential as means for solving the problems. For clarity of explanation, the following description and drawings are appropriately omitted and simplified. In each drawing, the same elements are designated by the same reference numerals, and redundant descriptions are omitted as necessary.

### (Example of Layout Configuration of Related Semiconductor Chip)

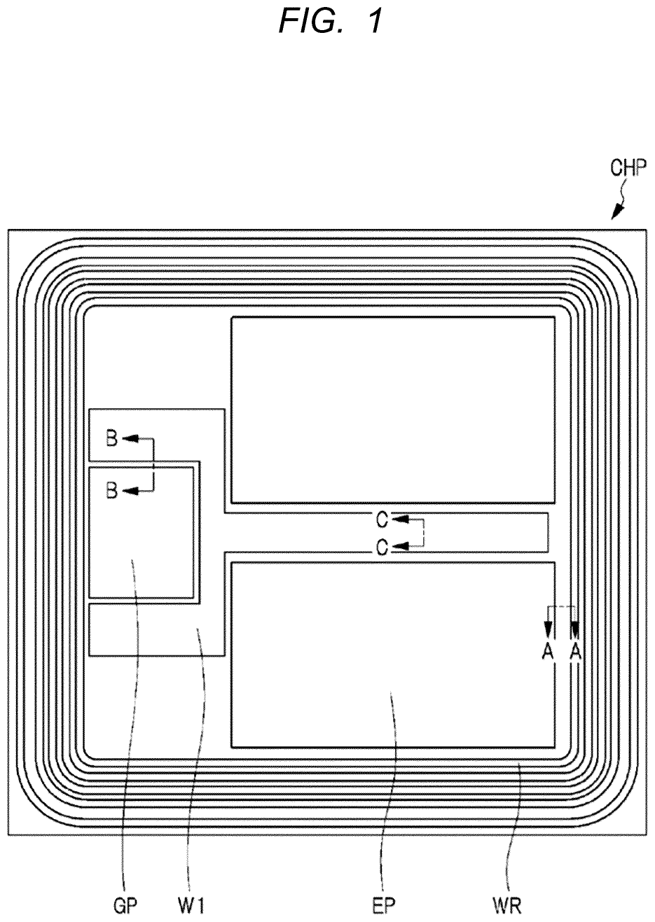

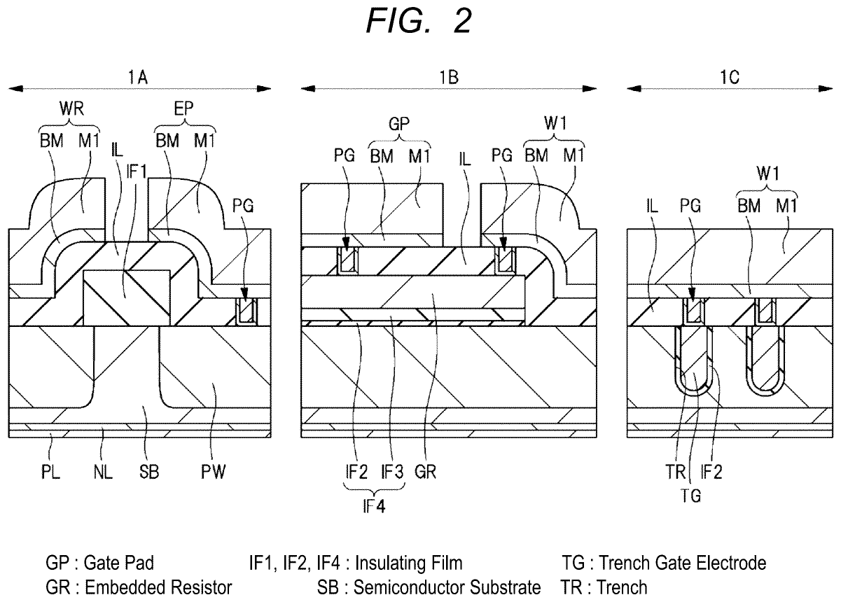

A semiconductor device equipped with a related IGBT will be described with reference to FIGS. 1 and 2. FIG. 1 is a schematic diagram showing an example of a layout configuration of a semiconductor chip on which the related semiconductor device is mounted. FIG. 2 is a cross-sectional view showing the related semiconductor device.

As shown in FIG. 1, the related semiconductor chip CHP has a rectangular planar shape. The semiconductor chip CHP, in plain view, has a gate pad GP, gate wiring W1, and an emitter pad EP. Moreover, on the bottom surface (back surface) opposite the upper surface of the semiconductor chip CHP, a collector electrode covering the bottom surface of the semiconductor substrate (not shown in FIGS. 1 and 2) is formed. On the upper surface side of the semiconductor chip CHP, in plain view, there exists an annular peripheral region formed along the contour of the semiconductor chip CHP, surrounding the gate pad GP, gate wiring W1, and emitter pad EP. On the upper surface of the semiconductor substrate in the peripheral region, for example, a Field Limiting Ring (FLR), which is a terminal structure, is formed. Furthermore, on the semiconductor substrate in the peripheral region, an annular wiring WR is formed.

In FIG. 2, regions 1A, 1B, and 1C are shown in order from left to right. The cross-section of region 1A depicted in FIG. 2 is a cross-section at line A-A in FIG. 1, the cross-section of region 1B is a cross-section at line B-B in FIG. 1, and the cross-section of region 1C is a cross-section at line C-C in FIG. 1. Region 1A is an area that includes a peripheral area surrounding regions 1B and 1C in a plan view. In FIG. 2, the device region (cell region) functioning as an IGBT is not shown.

The semiconductor device comprises an N-type semiconductor substrate SB and a P-type well PW formed from the upper surface of the semiconductor substrate SB to a predetermined depth within the semiconductor substrate SB. The P-type well PW is a semiconductor region formed across areas 1A, 1B, and 1C. Furthermore, within the semiconductor substrate SB, spaced apart from the lower end of the P-type well PW and formed near the lower surface of the semiconductor substrate SB, there is an N-type semiconductor layer NL having a higher impurity concentration than the semiconductor substrate SB, and a P-type semiconductor layer PL formed from the lower surface of the N-type semiconductor layer NL to the lower surface of the semiconductor substrate SB. In other words, the semiconductor substrate SB comprises, in order from the lower surface side, a P-type semiconductor layer PL, an N-type semiconductor layer NL, the semiconductor substrate SB, and a P-type well PW. In area 1A, on the semiconductor substrate SB, an insulating film IF1, which is a ring-shaped field oxide film, is formed, and directly beneath the insulating film IF1, the P-type well PW is not formed.

The semiconductor substrate SB is made of single crystal Si (silicon) into which N-type impurities such as P (phosphorus) have been introduced. The N-type semiconductor layer NL is a semiconductor region formed by introducing N-type impurities (for example, P (phosphorus)) into the semiconductor substrate SB. The N-type semiconductor layer NL functions as a buffer layer for IGBT. The P-type semiconductor layer PL and the P-type well PW are semiconductor regions formed by introducing P-type impurities (for example, B (boron)) into the semiconductor substrate SB. The P-type semiconductor layer PL is a layer that injects holes into the semiconductor substrate SB.

In region 1C, a trench TR is formed on the upper surface of the semiconductor substrate SB, and within the trench TR, a trench gate electrode TG is embedded through an insulating film IF2. The depth of the trench TR is shallower than the P-type well PW here, and the bottom end of the trench TR does not reach the bottom end of the P-type well PW. The trench gate electrode TG is constituted by a polysilicon film embedded in the trench through an insulating film IF2, which is a trench gate insulating film. The polysilicon film constituting the trench gate electrode TG is doped with, for example, phosphorus (P). Here, the polysilicon film and the insulating film IF2 constituting the trench gate electrode TG are not formed on the semiconductor substrate SB in the area outside the trench TR, that is, in the area that does not overlap with the trench TR in plain view.

In region 1B, an embedded resistor GR, for example, is formed on the upper surface of the semiconductor substrate SB via the insulating film IF4. The embedded resistor is a gate resistance element. Instead of the embedded resistor GR, a temperature sensing diode or a gate protection diode may be formed. The embedded resistor GR is formed directly above the P-type well PW. In other words, the embedded resistor GR overlaps with the P-type well PW in plain view. The insulating film IF4 is composed of the insulating films IF2 and IF3, which are sequentially laminated on the semiconductor substrate SB. This insulating film IF2 is made of a thermal oxide film formed in the same process as the insulating film IF2 formed in the trench TR of region 1C. Moreover, the insulating film IF3 is, for example, a TEOS film. Therefore, the thickness of the insulating film IF4 is greater than the thickness of the insulating film IF2 in the trench TR. In other words, the thickness of the insulating film between the embedded resistor GR and the upper surface of the semiconductor substrate SB is greater than the thickness of the insulating film between the surface of the trench TR and the trench gate electrode TG. The thickness of the insulating film IF4 is about 2 to 7 times that of the insulating film IF5 of the comparative example, specifically, for example, about 5 times.

Since the trench gate insulating film is formed only of the insulating film IF2, the insulating film IF2 is in contact with the surface of the semiconductor substrate SB (the surface of the trench TR) and the surface of the trench gate electrode TG, respectively. Here, because the trench gate insulating film, which is the insulating film IF2, is composed of a single layer of thermal oxide film, it is possible to prevent the occurrence of variations in the thickness of the trench gate insulating film compared to when the trench gate insulating film is a laminated structure of thermal oxide film and TEOS film. This allows for the reduction of variations in the threshold voltage Vth of the IGBT.

Moreover, the thickness of the insulating film IF4 is smaller than the thickness of the field oxide film (field insulating film), which is the insulating film IF1. This is because forming an insulating film IF4 thicker than the field oxide film would result in too great a thickness, potentially preventing accurate exposure in the photolithography process and normal patterning. The insulating film IF2 has a higher relative permittivity and a denser structure than the insulating film IF3.

The thickness of the insulating film IF3 is greater than the thickness of the insulating film IF4. The thickness of the insulating film IF4 is, for example, 100 to 700 nm, and more preferably, for example, 200 to 400 nm. The thickness of the insulating film IF2 is, for example, 70 nm or more, specifically, for example, 100 nm. That is, the shortest distance between the surface of the trench TR and the trench gate electrode TG is 70 nm or more. Moreover, the thickness of the insulating film IF3 is, for example, about 450 nm. The thickness of the insulating film IF1 is, for example, about 700 nm. The insulating film IF3 is not limited to a silicon oxide film and may be composed of, for example, a silicon nitride film. The insulating film IF1 is, for example, an annular pattern made of a silicon oxide film, which surrounds the device region, region 1B, region 1C, the emitter pad EP mentioned later, the gate pad GP, and the gate wiring W1 in plain view.

The embedded resistor GR is made of, for example, a polysilicon film and is a resistor that is made conductive by the introduction of as (arsenic). Herein, the embedded resistance GR and the trench gate electrode TG are spaced apart from each other. The embedded resistance GR is a resistance element comprising a resistor body serially connected between the gate pad GP and the trench gate electrode TG.

On the semiconductor substrate SB, an interlayer insulating film IL, for example, made of a silicon oxide film, is formed to cover the trench gate electrode TG, insulating films IF1 to IF4, and the embedded resistor GR. In the interlayer insulating film IL, connection holes that penetrate from the upper surface of the interlayer insulating film IL to the lower surface are opened at multiple locations, and plugs PG are embedded in the connection holes. The plug PG is composed of, for example, a TiN (titanium nitride)/Ti (titanium) film, which is a barrier metal film that continuously covers the bottom surface and side surfaces of the connection hole, and a W (tungsten) film embedded in the connection hole via the barrier metal film. The plug PG is connected to the upper surface of the P-type well PW in region 1A, the upper surface of the embedded resistor GR in region 1B at both ends, and the upper surface of the trench gate electrode TG. Here, in the direction along the upper surface of the semiconductor substrate SB, the width of the plug PG is smaller than the width of the trench gate electrode TG. Therefore, the bottom surface of the plug PG connected to the trench gate electrode TG is spaced apart from the upper surface of the semiconductor substrate SB.

On the interlayer insulating film IL and the plug PG, a laminated metal film consisting of a metal film BM and a metal film M1 formed on the metal film BM is formed. The metal film BM, which is a barrier metal film, consists of, for example, a TiW (titanium tungsten) film, and the metal film M1, which is a main conductor film, consists of, for example, an AlCu (aluminum copper) film. Also, the metal film M1 may be an AlSi film with Si added to the Al film. Among the multiple laminated metal films, those electrically connected to the P-type well PW through the plug PG in region 1A constitute an emitter pad (emitter electrode) EP. Among the multiple laminated metal films, those connected to the upper surface of one end of the embedded resistor GR through the plug PG in region 1B constitute a gate pad GP. Among the multiple laminated metal films, those connected to the upper surface of the other end of the embedded resistor GR through the plug PG in region 1B constitute a gate wiring W1. The gate wiring W1 is formed extending from region 1B to region 1C. The gate wiring W1 in region 1C is electrically connected to the trench gate electrode TG through the plug PG. The gate pad GP and the gate wiring W1 are spaced apart from each other.

Thus, the gate pad GP and the trench gate electrode TG are electrically connected through several plugs PG, the embedded resistor GR, and the gate wiring W1 connected in series between them. Specifically, the gate pad GP and the embedded resistor GR are electrically connected through the plug PG, the embedded resistor GR and the gate wiring W1 are electrically connected through the plug PG, and the gate wiring W1 and the trench gate electrode TG are electrically connected through the plug PG.

The emitter pad EP in region 1A supplies the emitter potential to the emitter region of the IGBT. The gate pad GP in region 1B supplies the gate potential to the trench gate electrode TG through the embedded resistor GR. In this way, the gate potential supplied to the trench gate electrode TG in region 1C is supplied to the trench gate electrode of the IGBT formed in the device region (not shown), thereby controlling the operation of the IGBT. The trench gate electrode TG and the P-type semiconductor layer (collector region) PL constitute the IGBT.

In the peripheral area surrounding the gate pad GP, gate wiring W1, and emitter pad EP in plain view, a wiring WR consisting of the laminated metal film separated from the emitter pad EP is formed.

### (Description of Auxiliary Elements and Protective Films Related to the Embodiment)

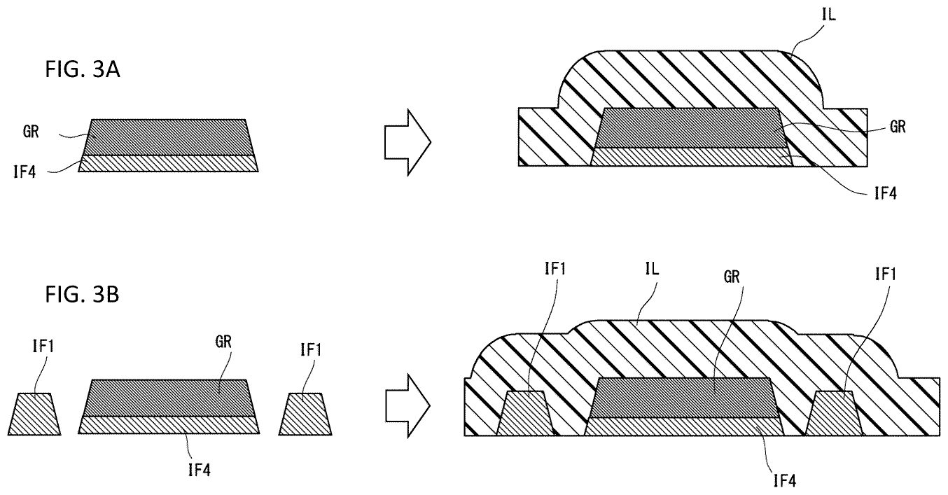

FIG. 3A is a cross-sectional view of the related auxiliary elements and the protective film covering them, and FIG. 3B is a cross-sectional view of the auxiliary elements related to the embodiment and the protective film covering them. The auxiliary elements related to the embodiment and the protective film covering them will be described with reference to FIGS. 3A and 3B.

As shown in FIG. 3A, the related auxiliary elements include a laminate of the first insulating film IF4 and the semiconductor layer GR. When laminating the protective film IL without using SOG (Spin on Glass) on the related auxiliary elements, the thickness of the first insulating film IF4 and the semiconductor layer GR is so great that a step is created between the auxiliary element and the semiconductor substrate SB. This step causes the formation of tungsten residues at the ends of the auxiliary elements when forming the tungsten plug PG. This tungsten residue can cause a short-circuit when further constructing the upper metal film M1.

Therefore, as shown in FIG. 3B, the auxiliary element according to the embodiment, similarly to the related auxiliary elements, includes a lamination of the first insulating film IF4 and the semiconductor layer GR. However, the auxiliary element according to the embodiment forms a boundary member around the auxiliary element, which includes the second insulating film IF1, to mitigate the step between the auxiliary element and the semiconductor substrate SB. The boundary member uses the second insulating film IF1, which was used for element separation. The height from the first main surface of the semiconductor substrate SB to the upper surface of the boundary member is lower than the height from the first main surface to the upper surface of the auxiliary element. That is, the thickness of the second insulating film IF1 is smaller than the thickness s of the semiconductor layer GR and the first insulating film IF4. The height of the boundary member is adjusted with the height of the auxiliary element as the upper limit to mitigate the step between the auxiliary element and the semiconductor substrate SB.

For the protective film IL, PSG (Phosphorous Silicate Glass) is used but SOG is not used. With such a configuration, a semiconductor device is provided that reduces the step in the protective film covering the auxiliary element by providing a boundary member between the auxiliary element and the main surface of the semiconductor substrate.

### (Description of a Method for Manufacturing a Semiconductor Device According to the Embodiment)

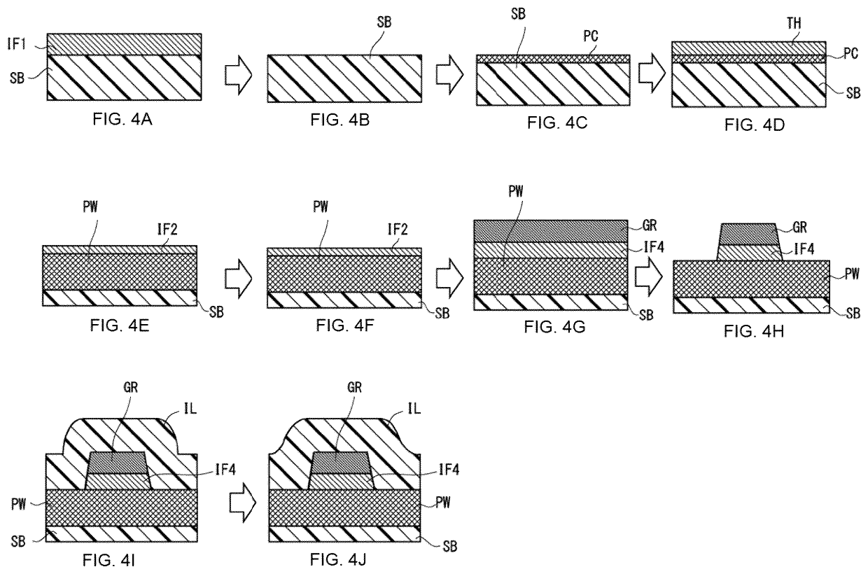

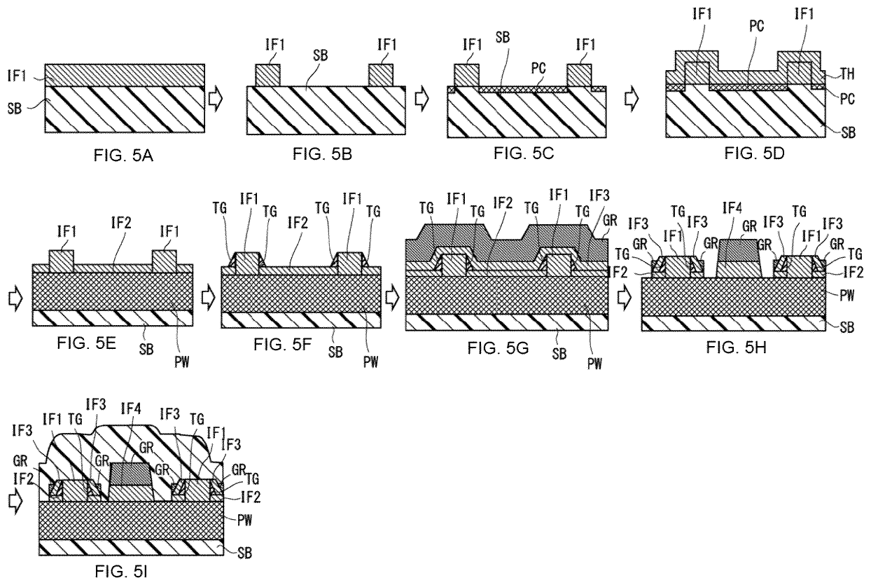

FIGS. 4A-4J are cross-sectional views showing a method for manufacturing a related auxiliary element. FIGS. 5A-5I are a cross-sectional view showing a method for manufacturing an auxiliary element according to the embodiment. With reference to FIGS. 4A-4J and 5A-5I, a method for manufacturing a semiconductor device according to the embodiment will be described.

As shown in FIGS. 4A-4J, the related auxiliary element first forms a second insulating film IF1 for element separation on the semiconductor substrate SB (FIG. 4A). Next, the second insulating film IF1 is removed (FIG. 4B), and a P-type impurity is introduced to form an impurity region PC (FIG. 4C).

Next, in order to embed the gate electrode in the first region where the IGBT is formed, an oxide film TH is formed, and a trench is created (FIG. 4D). Next, the formed oxide film is removed, sacrificial oxidation is performed, PC is diffused to form a P-type well PW, and then a gate insulating film IF2 is formed (FIG. 4E). Next, polysilicon TG for the gate electrode is formed and removed (FIG. 4F).

Next, on the gate insulating film IF2, an insulating film IF3 for relaxing the electric field of the auxiliary element is formed, and a semiconductor layer GR is laminated (FIG. 4G). The gate insulating film IF2 and the insulating film IF3 are referred to as the first insulating film IF4. The first insulating film IF4 and the semiconductor layer GR are patterned (FIG. 4H). A PSG, which is a protective film IL, is laminated on the semiconductor layer GR (FIG. 4I). Finally, SOG is applied, and the auxiliary element is completed (FIG. 4J).

The method for manufacturing an auxiliary element according to the embodiment is described with the area where the transistor is formed as the first region, the area where the auxiliary element is formed as the second region, and the area where the boundary member is formed as the third region. As shown in FIG. 5A, the auxiliary element according to the embodiment first forms a second insulating film IF1 for element isolation on the semiconductor substrate SB. Next, the second insulating film IF1 in the second region is removed, leaving the second insulating film IF1 in the third region (FIG. 5B). Next, a P-type impurity is introduced into the second region to form an impurity region PC (FIG. 5C).

The next step involves embedding a gate electrode in the first region by forming an oxide film TH in the first, second, and third regions, and then creating a trench in the first region (FIG. 5D). Subsequently, the oxide film TH formed in the first, second, and third regions is removed, sacrificial oxidation is performed, PC is diffused, and a P-type well PW is formed. After that, a gate insulating film IF2, which is the third insulating film, is formed on the P-type well PW. Then, the third insulating film IF2 in the third region is removed (FIG. 5E).

Next, polysilicon TG for the gate electrode is formed in the first region, and the polysilicon TG for the gate electrodes in the second and third regions is removed (FIG. 5F). At this time, in the third region, the semiconductor layer TG, which is the second semiconductor layer, is formed on the sidewall of the second insulating film IF1. Next, the fourth insulating film IF3, for the purpose of relaxing the electric field of the auxiliary element, is formed on the third insulating film in the second region and on the second insulating film in the third region, and the semiconductor layer GR, which is the first semiconductor layer, is stacked on the fourth insulating film IF3 (FIG. 5G). Here, the gate insulating film IF2 and the fourth insulating film IF3 are referred to as the first insulating film IF4.

Next, the fourth insulating film IF3 and the first semiconductor layer GR in the third region are removed (FIG. 5H). At this time, the fourth insulating film IF3 and the first semiconductor layer GR are formed on the sidewall of the second insulating film IF1 in the third region. A protective film IL, which is PSG, is laminated on the semiconductor layer in the second region and on the second insulating film in the third region, thereby completing the auxiliary element (FIG. 5I).

Thus, the method for manufacturing a related auxiliary element and the method for manufacturing an auxiliary element according to the embodiment are composed of the same construction materials. Furthermore, the number of processes has not increased. That is, an auxiliary element according to the embodiment can be manufactured simply by leaving the second insulating film IF1 around the auxiliary element. Moreover, since the process of applying SOG can be eliminated, the cost is reduced.

### (Configuration on the Plane of the Boundary Member According to the Embodiment)

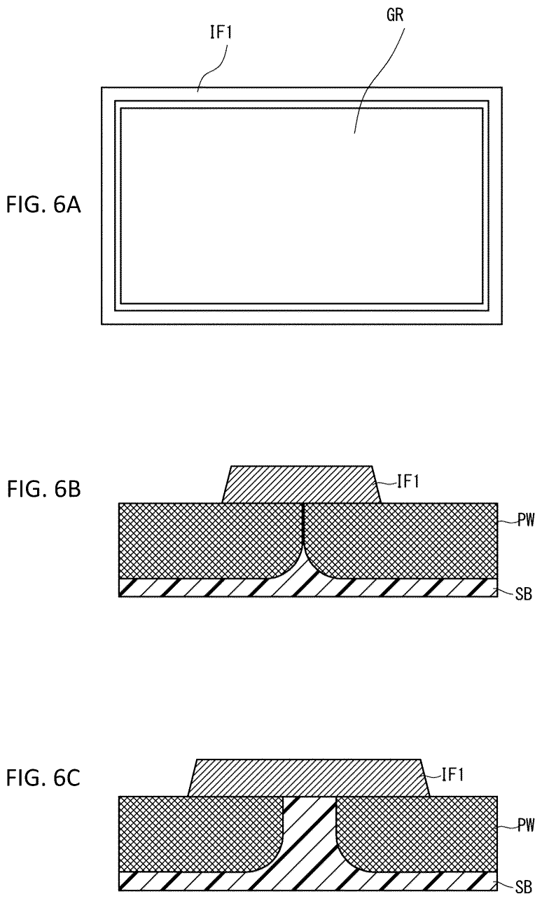

FIG. 6A is a top view of the auxiliary element and the boundary member, and FIGS. 6B and 6C are cross-sectional views showing the limits of the width of the boundary member. The configuration on the plane of the boundary member according to the embodiment will be described with reference to FIGS. 6A-6C.

As shown in FIG. 6A, the boundary member IF1 surrounds the semiconductor layer GR constituting the auxiliary element in a plan view. Referring to FIG. 1 in conjunction, the first main surface of the semiconductor substrate SB constituting the semiconductor device includes a first region represented by EP, and second and third regions represented by B-B. The semiconductor device has transistors formed in the first region, the auxiliary element formed in the second region, and the boundary member formed in the third region. The semiconductor device has the third region between the first and second regions, and the third region surrounds the second region in a plan view.

Mention is made of the limit of the width of the boundary member. In FIG. 6B, a P-type well PW is formed across the entire lower part of the second insulating film IF1, which is a boundary member. On the other hand, FIG. 6C shows that the P-type well PW is discontinuous under the second insulating film IF1, which is a boundary member. Under the second insulating film IF1, a P-type well PW must be formed across the entire area as shown in FIG. 6B.

P-type well PW extends about 5 μm (micrometers) by diffusion from the implanted location. As shown in FIG. 5C, the boundary member serves as a mask for implantation. Therefore, the width of the boundary member is preferably 10 μm (micrometers) or less.

In FIG. 6A, the corners of the boundary member are represented as right angles in plain view. However, to soften the steps, the corners of the boundary member may be rounded in plan view.

For example, in the semiconductor device according to the embodiment described above, it is possible to have a configuration where the conductivity type (p-type or n-type) of the semiconductor substrate, semiconductor layer, diffusion layer (diffusion region), etc., is reversed. Therefore, in the case where one of the conductivity types of the n-type and the p-type is designated as the first conductivity type and the other conductivity type is designated as the second conductivity type, it is possible to make the first conductivity type the p-type and the second conductivity type the n-type, or conversely, the first conductivity type can be the n-type and the second conductivity type can be the p-type.

Explanations were presented while changing the names for the symbols. This is because the names vary depending on areas. Locations with the same symbol are manufactured in the same process.

Although the invention made by the inventor has been specifically described based on the embodiment, the present invention is not limited to the embodiment already described, and it is needless to say that various modifications can be made without departing from the gist thereof.

What is claimed is:

1. A semiconductor device comprising:
a semiconductor substrate comprising a first main surface having a first region, a second region, and a third region located between said first region and said second region in plan view;
a transistor formed in said first region;
an auxiliary element formed in said second region;
a boundary member formed in said third region; and
a protective film covering said auxiliary element and said boundary member;
wherein the height from said first main surface to the upper surface of said boundary member is lower than the height from said first main surface to the upper surface of said auxiliary element.

2. The semiconductor device of claim 1 wherein said third region surrounds the periphery of said second region in plan view.

3. The semiconductor device of claim 1 wherein said auxiliary element is a gate resistance element, a temperature sensing diode, or a gate protection diode.

4. The semiconductor device of claim 1 wherein said protective film is a PSG (Phosphorous Silicate Glass) film.

5. The semiconductor device of claim 1 wherein said transistor is an IGBT (Insulated Gate Bipolar Transistor).

6. The semiconductor device of claim 1 wherein said auxiliary element comprises a stack of a first insulating film and a semiconductor layer.

7. The semiconductor device of claim 6 wherein said boundary member comprises a second insulating film different from said first insulating film.

8. A method for manufacturing a semiconductor device, comprising:
forming a second insulating film in a first region, a second region, and a third region located between said first region and said second region in plan view on the first main surface of a semiconductor substrate;
removing said second insulating film on said second region;
forming a third insulating film on said second region and said third region;
removing said third insulating film on said third region;
forming a fourth insulating film on said second region and said third region, wherein the stack of said third insulating film and said fourth insulating film on said second region is a first insulating film;
forming a first semiconductor layer on said second region and said third region;
removing said first semiconductor layer and said fourth insulating film on said third region;
forming an auxiliary element comprising said first insulating film and said first semiconductor layer on said second region, and a boundary member comprising said second insulating film on said third region; and
forming a protective film on said auxiliary element and said boundary member.

9. The method of claim 8 wherein said fourth insulating film and said semiconductor layer are formed on the sidewalls of said second insulating film in said third region.

10. The method of claim 8 wherein said third region surrounds the periphery of said second region in plan view.

11. The method of claim 8 wherein said auxiliary element is a gate resistance element, a temperature sensing diode, or a gate protection diode.

12. The method of claim 8 wherein said protective film is a PSG (Phosphorous Silicate Glass) film.

13. The method of claim 8 wherein said first region is where an IGBT (Insulated Gate Bipolar Transistor) is formed.

14. The method of claim 8, further comprising forming a second semiconductor layer on said third insulating film on said second region and said third region;
removing said second semiconductor layer on said second region and said third region;
wherein said second semiconductor layer is formed on the sidewalls of said second insulating film in said third region.

15. The method of claim 13 wherein said first semiconductor layer is used for said IGBT.
